(19) United States
(12) Patent Application Publication
(10) Pub. No.: US 2016/0064243 A1
(43) Pub. Date: Mar. 3, 2016

(54) CHEMICAL PLANARIZATION METHOD AND APPARATUS

(71) Applicant: KABUSHIKI KAISHA TOSHIBA, Tokyo (JP)

(72) Inventors: Akifumi GAWASE, Kuwana (JP); Yukiteru MATSUI, Nagoya (JP)

(73) Assignee: KABUSHIKI KAISHA TOSHIBA

(21) Appl. No.: 14/643,816

(22) Filed: Mar. 10, 2015

(30) Foreign Application Priority Data
Sep. 3, 2014 (JP) 2014-179438

(51) Int. Cl. H01L 21/3105; H01L 21/311; H01L 21/67

(52) U.S. Cl. CPC H01L 21/31055; H01L 21/67075; H01L 21/67092; H01L 21/31111

(57) ABSTRACT

A chemical planarization method according to an embodiment includes a step of forming a hydrophobic protective film on a film to be processed with surface asperity. A dissolving solution for dissolving the film to be processed is supplied to the surface of the protective film. A processing body with a hydrophobic surface is brought into contact with or brought closed to the protective film, and a portion of the protective film is selectively removed by hydrophobic interaction from the film to be processed. The film to be processed is dissolved by the dissolving solution after the portion of the protective film is removed.

### CROSS REFERENCE TO RELATED APPLICATION(S)

This application is based upon and claims the benefit of priority from the prior Japanese Patent Application No. 2014-179438, filed on Sep. 3, 2014, the entire contents of which are incorporated herein by reference.

### FIELD

Embodiments described herein relate generally to a chemical planarization method and apparatus.

### BACKGROUND

In recent years, in the manufacture of semiconductor devices, chemical mechanical polishing (CMP) methods have been widely used for the planarization of insulating films, metallic films, and polycrystalline silicon films, or the like formed to fill grooves. The CMP method refers to a method of polishing a surface to be processed by supplying an abrasive (slurry) containing abrasive grains and a chemical onto an abrasive cloth, and bringing the surface to be processed into contact with the abrasive cloth. The surface to be processed is polished and planarized by the chemical action of the chemical and the mechanical action of the abrasive grains. However, this method has the problem of mechanical damage caused to the surface to be processed caused by the abrasive grains or the polishing.

In order to solve this problem, chemical planarization methods have been examined which avoid damage to the surface to be processed through the use of a treatment liquid containing any abrasive grains. For example, a method of carrying out planarization of a metallic film surface by chemically dissolving, with a treatment liquid, a portion increased in temperature in contact with an abrasive cloth, and a method of carrying out planarization of a silicon film, a silicon carbide film, a gallium nitride film, an aluminum oxide film, and a metallic film by bringing a surface to be processed into contact with a solid plate including a catalyst and chemically dissolving the contact region have been proposed as the chemical planarization methods,

However, it is difficult to apply the chemical planarization methods to the planarization of silicon oxide films, which is essential for the manufacture of semiconductor devices, and even when the methods are applied thereto, the methods are insufficient because of significantly low processing speeds as compared with CMP methods.

While a method of forming a protective film on a surface to be processed, mechanically removing the protective film on a convex part, and dissolving only the part in a treatment liquid has been proposed as a chemical planarization method for silicon oxide films, this method have the possibility of causing damage to the surface to be processed when the protective film is mechanically removed.

### BRIEF DESCRIPTION OF THE DRAWINGS

FIGS. 1A to 1D are cross-sectional views schematically illustrating a film to be processed in each step of a chemical planarization method according to an embodiment;

FIG. 2 is a flowchart showing steps of a chemical planarization method according to an embodiment;

FIGS. 3A to 3D are cross-sectional views schematically illustrating a film to be processed in each step of a chemical planarization method according to a first example; and

FIG. 4 is a schematic configuration diagram illustrating a chemical planarization apparatus according to an embodiment.

### DETAILED DESCRIPTION

Embodiments will now be explained with reference to the accompanying drawings. The present invention is not limited to the embodiments.

A chemical planarization method according to an embodiment includes a step of forming a hydrophobic protective film on a film to be processed with surface asperity. A dissolving solution for dissolving the film to be processed is supplied to the surface of the protective film. A processing body with a hydrophobic surface is brought into contact with or brought closed to the protective film, and a portion of the protective film is selectively removed by hydrophobic interaction from the film to be processed. The film to be processed is dissolved by the dissolving solution after the portion of the protective film is removed.

An embodiment of the present invention will be described below with reference to the drawings. In the following description, the drawings are shematic and conceptual, the relationship between the thickness and width of each part, the ratio in size between parts, or the like are not necessarily identical to those of real parts. In addition, even when the same part is shown, the dimensions and ratios thereof may be shown differently from each other depending on the drawings. Moreover, in the specification and respective drawings of the present application, the same elements as described previously with reference to the already mentioned drawings are denoted by the same reference numerals, and detailed descriptions of the elements will be omitted appropriately.

### (Chemical Planarization Method)

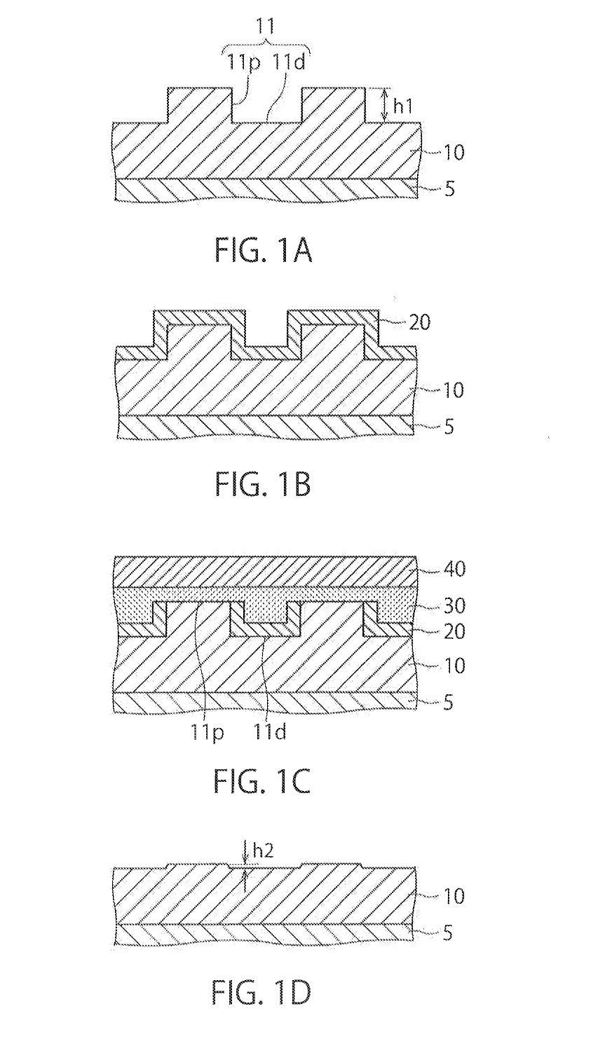

A chemical planarization method according to an embodiment will be described with reference to FIGS. 1A through 3D, FIGS. 1A to 1D are cross-sectional views schematically illustrating a film to be processed in each step of the chemical planarization method.

First, a film to be processed 10 will be described with reference to FIG. 1A. The film to be processed 10 is subject to processing by the chemical planarization method, and the surface of the film to be processed 10 is a surface to be processed. The film to be processed 10 is, but not limited thereto, for example, a silicon oxide film, silicon film, a silicon carbide film, a gallium nitride film, an aluminum oxide film, and a metallic film.

The film to be processed 10 has surface asperity 11, as shown in FIG. 1A. The asperity 11 is composed of a convex part lip and a concave part 11d. The depth hi of the asperity 11, that is the distance h1 from the surface of the convex part 11p to the surface of the concave part lid is, for example, 30 nm or more and 5000 nm or less.

The film to be processed 10 is formed on the surface of a substrate 5 by any method depending on the material, such as a Chemical Vapor Deposition (CVD) method, a Physical Vapor Deposition (PVD) method, and an application method. The substrate 5 is, but not limited thereto, for example, a substrate for a semiconductor device, such as a semiconductor memory, a high-speed logic LSI, a system LSI, and a memory-logic consolidated LSI.

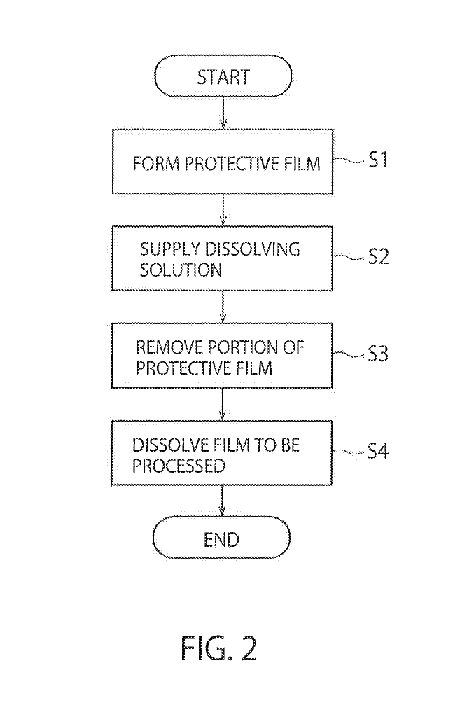

FIG. 2 herein is a flowchart showing steps of the chemical planarization method.

In Step S1, first, a protective film 20 is formed. As shown in FIG. 1B, the protective film 20 is formed on the film to be processed 10 so as to follow the asperity 11. The protective film 20 serve to protect the film to be processed 10 from a dissolving solution 30 in a step of dissolving the film to be processed 10 described below. For this reason, the protective film 20 is formed from a material that is insoluble or poorly soluble in the dissolving solution 30. The term of poorly soluble herein means that the solubility in the dissolving solution 30 is lower than the solubility of the film to be processed 10 in the dissolving solution 30.

In addition, the protective film 20 is formed to have a hydrophobic surface. The degree of hydrophobicity is able to be measured by contact angle measurement (for example, JIS R 3257) or the like. The contact angle at the surface of the protective film 20 is preferably, for example, 90° or more.

The material of the protective film 20 has a hydrophobic group constituting the surface of the protective film 20, and a binding site that binds to the surface of the film to be processed 10. This material is selected so that binding between the surface of the film to be processed 10 and the binding site is weaker than binding by hydrophobic interaction produced between a processing body 40 described below and the hydrophobic group. The material of the protective film 20 is, but not limited thereto, for example, a surfactant. The surfactant will be described later.

In Step S2, the dissolving solution 30 is supplied to the surface of the protective film 20. The dissolving solution 30 is a solution that is able to dissolve the film to be processed 10. In addition, the dissolving solution 30 is a solution containing a polar solvent such as water molecules (for example, an aqueous solution). The dissolving solution 30 is selected depending on the film to be processed 10. For example, when the film to be processed 10 is a silicon oxide film, an aqueous solution containing at least one of a hydrogen fluoride aqueous solution, an ammonium fluoride aqueous solution, and a strong alkaline aqueous solution is used as the dissolving solution 30.

In Step S3, a portion of the protective film 20 formed on the film 10 to be processed is removed. In Step S3, in order to remove a portion of the protective film 20, the processing body is brought into contact with or brought close to the protective film 20 in the dissolving solution 30.

The processing body 40 is formed from, for example, a fluorine-containing polymer such as polytetrafluoroethylene, a silicon-containing polymer, and a hydrocarbon-containing polymer. These materials are hydrophobic, and the surface of the processing body 40, which is opposed to the protective film 20, (hereinafter, referred to as “processing surface”) is thus hydrophobic. The degree of hydrophobicity at the processing surface is able to be measured by contact angle measurement (for example, JIS R 3257:1999) or the like. The contact angle at the processing surface is preferably, for example, 90° or more. The processing body 40 may have a single layer structure, or a stacked structure of two or more layers. When the processing body 40 has a stacked structure, the stacked structure may include therein a hydrophilic layer as long as the processing surface is hydrophobic.

When this processing body 40 is brought into contact with or brought closed to the protective film 20 in the dissolving solution 30, hydrophobic interaction is exerted between the hydrophobic processing surface and the hydrophobic surface of the protective film 20. Thus, the protective film 20 on the convex part 11p, which is brought into contact with or brought close to the processing surface, is adsorbed onto the processing surface, and removed from the film to be processed 10. It is to be noted that the term of brought close herein means that the processing body 40 and the protective film 20 are brought close to each other to the extent that the protective film 20 on the convex part lip is able to be removed.

In contrast, the protective film 20 on the concave part 11d, which is just at least the depth hi away from the processing surface, is not adsorbed onto the processing surface, but left on the film to be processed 10. This is because the hydrophobic interaction is rapidly weakened with distance.

Thus, as shown in FIG. 1C, the protective film 20 on the convex part 11p can be selectively removed while leaving the protective film 20 on the concave part 11d. As described above, any mechanical method such as polishing is not used in removing the protective film 20, and mechanical damage to the film to be processed 10 can be thus suppressed.

In Step S4, the film to be processed 10 is dissolved by the dissolving solution 30. The convex part lip of the film to be processed 10 is brought into contact with the dissolving solution 30, because the protective film 20 on the convex part 11p is selectively removed in Step S3. In contrast, the concave part lid of the film to be processed 10, which is covered with the protective film 20, is thus not brought into contact with the dissolving solution 30. As described above, the protective film 20 has lower solubility in the dissolving solution 30 than the film to be processed 10, the convex part lip with the protective film 20 removed therefrom is thus higher in dissolution rate than the concave part lid covered with the protective film 20.

Therefore, when the film to be processed 10 is dissolved by the dissolving solution 30, the depth h2 of the asperity 11 after the dissolving step is smaller than the depth h1 of the asperity 11 before the dissolving step as shown in FIG. 1D. The film to be processed 10 can be planarized by continuing the dissolving step for a predetermined period of duration. The duration of the dissolving step can be set in advance so that the depth h2 of the asperity 11 is 0, or equal to or less than a predetermined value. Alternatively, the timing of finishing the dissolving step may be determined by measuring the depth h2 during the dissolving step.

It is to be noted that the processing body 40 and the protective film 20 are brought into contact with or brought closed to each other continuously or at a predetermined time interval in the dissolving step. This is because the protective film 20 formed on side surfaces of the concave part lid and convex part lip is removed depending on the dissolution of the convex part 11p.

The chemical planarization method according to the present embodiment as described above can suppress damage to the surface to be processed, and efficiently achieve planarization. The reason is as follows.

According to a mechanical planarization method (e.g., lapping) in the past, the film to be processed 10 can be planarized by selectively polishing the film to be processed 10 from the convex part lip thereof, In this planarization method, the depth of the film to be processed 10, which is subjected to polishing for planarization, is almost equal to the depth hi of the asperity 11, the processing time is short, and the amount of processing the film 10 to be processed is small. More specifically, planarization can be achieved efficiently, However, it is difficult to apply the planarization method to the manufacture of fine elements which require high performance or a high degree of accuracy, because the surface of the film to be processed 10 is damaged significantly by the polishing.

Further, as a CMP method for silicon oxide films, a method has been proposed which uses slurry obtained by adding a surfactant to abrasive grains of CeO₂. In this CMP method, planarization is carried out with a wafer in direct contact with a polishing pad, and damage by the polishing is thus likely to be caused as in the mechanical planarization method described above. In addition, it is also determined that scratch on the surface to be processed, which is induced by the abrasive grains in the slurry, becomes a factor in lowering the yield.

In contrast, in the chemical planarization method according to the present embodiment, the film to be processed 10 can be planarized by the dissolving solution 30 containing no abrasive grains. Therefore, this chemical planarization method can suppress damage to the surface to be processed, which is caused by polishing or abrasive grains. Therefore, the method can be applied to the manufacture of fine elements, and suppress lowering of the yield.

In addition, in a chemical planarization method (such as wet etching) in the past, isotropic etching is carried out with, for example, an etchant. This planarization method causes no mechanical damage to the surface to be processed. However, considerably deeper etching than the depth h1 of the asperity 11 is required for planarization, because there is no substantial difference between the etching rate of the convex part lip and the etching rate of the concave part 11d. For this reason, the processing time is longer, and the amount of processing the film to be processed 10 for planarization is increased. More specifically, planarization can be achieved inefficiently. In addition, in some cases, there is also a possibility that flatness will be deteriorated by etch pit after all.

In contrast, the chemical planarization method according to the present embodiment can selectively remove the protective film 20 on the convex part lip, and selectively dissolve the convex part lip. For this reason, the thickness of the film to be processed 10 dissolved for planarization is almost equal to the depth h1 of the asperity 11. Therefore, this chemical planarization method can achieve planarization efficiently, with the processing time shortened and the reduced amount of processing the film to be processed 10.

Furthermore, the chemical planarization method according to the present embodiment has no limitation on the material of the film to be processed 10, but can be applied to planarization of silicon oxide films for forming element isolation regions and metal insulating films, and thus has a great deal of potential.

Examples of the chemical planarization method according to the present: embodiment will be described below.

### First Example

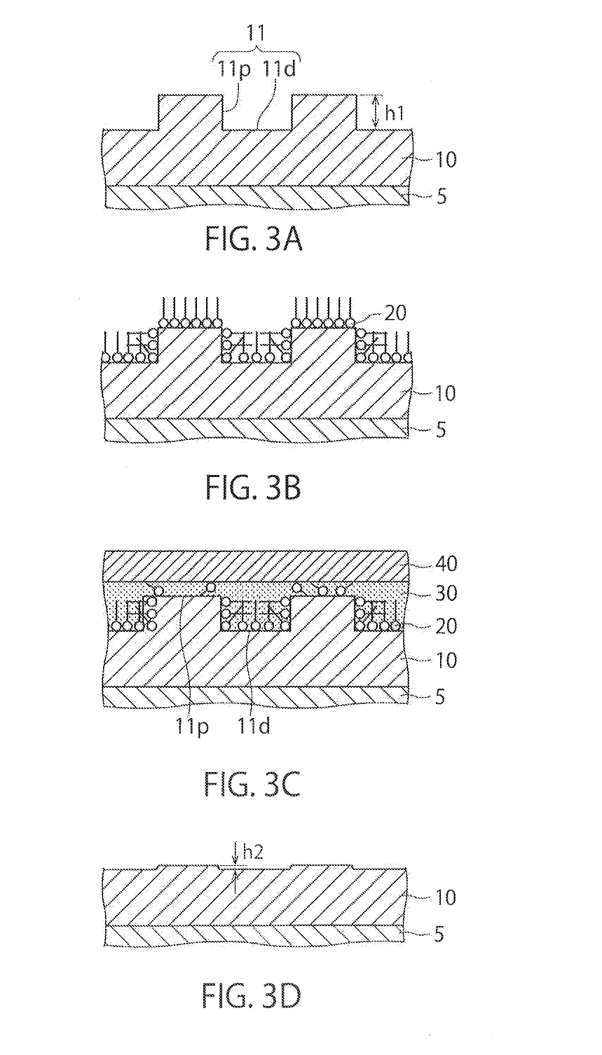

In the first example, the protective film 20 is formed from a surfactant. FIGS. 3A to 3D are cross-sectional views schematically illustrating a film to be processed in each step of a chemical planarization method according to the present example.

In the present example, the substrate 5 shown in FIG. 3A is a silicon substrate, and the film to be processed 10 therein is a silicon oxide film. Elements (not shown) such as transistors are formed on the surface of the substrate 5. The film to be processed 10 is formed on the substrate 5 by a CVD method or an application method so as to embed asperity formed by the elements. For this reason, the surface of the film to be processed 10 has asperity 11 caused by the asperity of the elements formed on the surface of the substrate 5. In addition, the surface of the film to be processed 10 is made hydrophilic by any surface treatment.

When a surfactant is applied to the surface of the film to be processed 10, hydrophilic groups of the surfactant are adsorbed or bound to the surface of the film to be processed 10 to form the protective film 20 including the surfactant as shown in FIG. 3B (Step S1). Hydrophobic groups of the surfactant are exposed at the surface of the protective film 20, and the surface of the protective film 20 is hydrophobic. More specifically, the hydrophilic groups of the surfactant serve as binding sites in the present example.

Anionic, cationic, ampholytic, non-ionic surfactants can be used as the surfactant for forming the protective film 20. In addition, functional groups preferably used for the surfactant include, for example, functional groups of carboxylic acid type, sulfonic acid type, sulfate type, phosphate type, amine salt type, quaternary ammonium salt type, ether type, ester type, alkanolamide type, carboxybetaine type, and glycine type.

Furthermore, the hydrophilic groups of the surfactant preferably have electrically reverse polarity of the film to be processed 10. This allows the hydrophilic groups to be strongly adsorbed by electrical interaction to the surface of the film to be processed 10, and allows the protective film 20 to be formed in a stable fashion. For example, when the surface of the film to be processed 10 is negatively charged, it is preferable to use, as the surfactant, a cationic surfactant such as polyvinylpyrrolidone and polyethyfeneimine.

Next, the dissolving solution 30 is supplied to the surface of the protective film 20 (Step S2). In the present example, for example, a hydrogen fluoride aqueous solution, an ammonium fluoride aqueous solution, or a strongly alkaline aqueous solution such as potassium hydroxide or ammonia can be used as the dissolving solution 30, because the film to be processed 10 is a silicon oxide film.

Then, the processing body 40 is brought into contact with or brought close to the protective film 20 in the dissolving solution 30. Thus, as shown in FIG. 3C, the surfactant adsorbed or bound onto the convex part lip is adsorbed by hydrophobic interaction to the processing surface, and selectively removed from the surface of the convex part lip (Step S3).

When the protective film 20 on the convex part lip is removed, the convex part lip of the film to be processed 10 is selectively dissolved by the dissolving solution 30 (Step S4). At the timing when the depth h2 of the asperity 11 after the dissolution reaches zero, or equal to or less than a predetermined value, or after continuing the dissolving step for a predetermined period of duration, the dissolving solution 30 is removed from the surface of the film to be processed 10. Thus, the surface of the film to be processed 10 is planarized as shown in FIG. 3D.

As in the present example, when the protective film 20 is formed from a surfactant, the protective film 20 on the convex part lip can be effectively removed by hydrophobic interaction. For this reason, in the present example, planarization can be effectively carried out, because of the high processing selectivity (dissolution rate ratio) of the concave part: lip to the concave part lid. In addition, mechanical damage to the film to be processed 10 can be suppressed, because the dissolving solution 30 contains therein no abrasive grains, without carrying out polishing.

### Second Example

In the second example, the dissolving solution 30 contains therein a material for the protective film 20. The other configuration is the same as in the first example. More specifically, the dissolving solution 30 contains therein a surfactant.

In the present example, the dissolving solution 30 is supplied to the surface of the film to be processed 10 to form the protective film 20. When the dissolving solution 30 is supplied, the surfactant contained in the dissolving solution 30 is adsorbed or bound to the surface of the film to be processed 10 to form the protective film 20 on the film to be processed 10.

As just described, in the present example, the step of forming the protective film 20 and the step of supplying the dissolving solution 30 are carried out at the same time, and the steps can be thus simplified. After the formation of the protective film 20 and the supply of the dissolving solution 30, it is possible to achieve planarization in accordance with the same steps as in the first example.

### Third Example

In the third example, the protective film 20 is relatively moved with respect to the processing body 40, while the film is in contact with or closed to the processing body 40. The relative movement is achieved by moving the processing body 40 with the protective film 20 at rest, moving the protective film 20 with the processing body 40 at rest, or moving the both so as to change the relative position between the protective film 20 and the processing body 40. In the present example, as just described, the relative movement of the protective film 20 can remove the protective film 20 more efficiently than in the case of the first example or second example.

In addition, in the present example, it is preferable to use the processing body 40 with the processing surface low in coefficient of friction. The coefficient of friction at the processing surface is able to be measured by a ball-on-disc method (for example, JIS R 1613: 2010) or the like. The coefficient of friction at the processing surface is, for example, 0.15 or less. This processing body 40 can be formed from, for example, a fluorine-containing polymer such as polytetrafluoroethylene, or fluorine-containing diamond-like carbon.

As just described, the use of the processing body 40 with the processing surface low in coefficient of friction can mechanical damage caused on the film to be processed 10 by the relative movement of the protective film 20. Furthermore, when the protective film 20 is relatively moved, the processing body 40 is preferably brought close to the protective film 20, but not into contact therewith. This can further suppress mechanical damage caused on the film to be processed 10.

### (Chemical Planarization Apparatus)

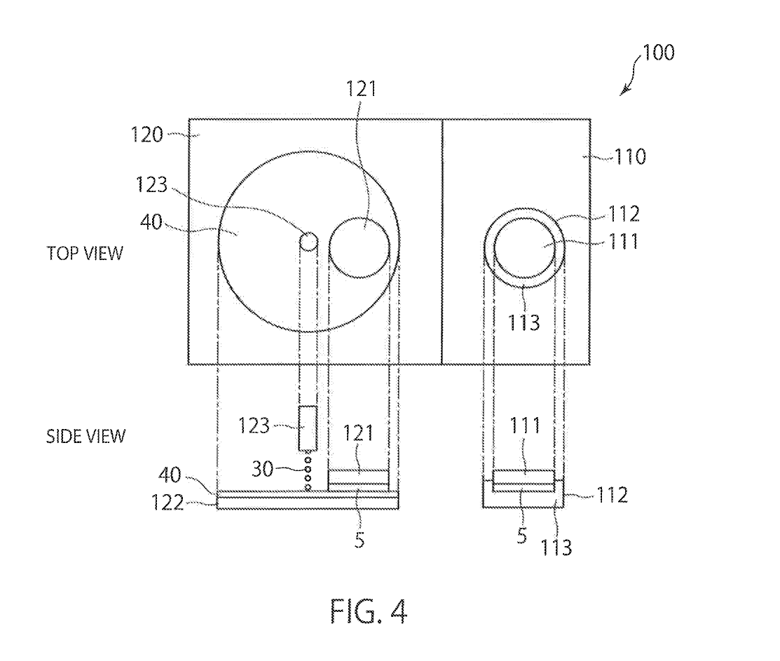

Next, a chemical planarization apparatus 100 according to an embodiment will be described with reference to FIG. 4. The chemical planarization apparatus 100 according to the present embodiment achieves the chemical planarization method according to the present embodiment. FIG. 4 is a schematic configuration diagram illustrating the chemical planarization apparatus 100. FIG. 4 has, in an upper section and a lower section thereof, a top view and a side view of the chemical planarization apparatus 100, respectively. As shown in FIG. 4, the chemical planarization apparatus 100 includes a pretreatment unit 110 and a planarizing unit 120,

The pretreatment unit 110 includes a substrate holder 111 and a container 112, The substrate holder 111 holds the substrate 5 with the film to be processed 10 formed on the surface thereof, from the back surface and rear surface of the substrate, The container 112 stores a pretreatment liquid 113. The pretreatment liquid 113 contains, for example, a material for the protective film 20, such as a surfactant.

The planarizing unit 120 includes a substrate holder 121, a processing body holder 122, and a dissolving solution supplier 123, The substrate holder 121 holds the substrate 5 with the film to be processed 10 formed on the surface thereof, from the back surface and rear surface of the substrate. The processing body holder 122 holds the processing body 40 so that the film to be processed 10 of the substrate 5 held in the substrate holder 121 is opposed to the processing surface of the processing body 40. The dissolving solution supplier 123 supplies the dissolving solution 30 onto the processing surface of the processing body 40.

This chemical planarization apparatus 100 first immerses the substrate in the pretreatment liquid 113 in the container 112, while the substrate 5 is held by the substrate holder 111,

Thus, the material for the protective film 20, which is contained in the pretreatment liquid 113, is bound or adsorbed to the surface of the film to be processed 10 to form the protective film 20 on the film to be processed 10 (Step S1),

Next, the dissolving solution supplier 123 supplies the dissolving solution 30 onto the processing surface. Then, the substrate holder 121 brings the film to be processed 10 into contact with or close to the processing body 40, while holding the substrate 5. Thus, the dissolving solution 30 is supplied onto the film to be processed 10 (Step S2), Furthermore, the protective film 20 formed on the concave part lip of the film to be processed 10 is selectively removed by bringing the film to be processed 10 and the processing body 40 into contact with or close to each other (Step S3).

The substrate holder 121 keeps the film to be processed 10 in contact with or close to the processing body 40. Thus, the convex part 11p is selectively dissolved by the dissolving solution 30 (Step S4). Then, after an elapse of a predetermined period of duration, the substrate holder 121 moves the film to be processed 10 away from the processing body 40. Thus, the dissolution treatment is completed to achieve planarization of the film to be processed 10. The duration of dissolution treatment may be set in advance. Alternatively, the timing of completion of the dissolution treatment may be determined by measuring the film thickness of the film to be processed 10 and the depth h2 of the asperity 11 through light irradiation below the processing body holder 122.

As described above, the chemical planarization apparatus 100 according to the present embodiment can implement the chemical planarization method according to the present embodiment. Therefore, mechanical damage and damage by abrasive grains to the film to be processed 10 can be suppressed to achieve efficient planarization of the film to be processed 10.

It is to be noted that the material for the protective film 20 may be contained in the dissolving solution 30 as described in the second example. In this case, the chemical planarization apparatus 100 may not include the pretreatment unit 110.

In addition, at least one of the substrate holder 121 and processing body holder 122 may have the function of rotation and the function of movement in planar directions. Thus, as described in the third example, the protective film 20 can be efficiently removed by relative movement of the protective film 20 brought into contact with or closed to the processing body 40.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A chemical planarization method comprising:
forming a hydrophobic protective film on a film to be processed with surface asperity;
supplying, onto the surface of the protective film, a dissolving solution for dissolving the film to be processed;
bringing a processing body with a hydrophobic surface comprising a fluorine-containing polymer or a silicon-containing polymer into contact with or close to the protective film to remove selectively a portion of the protective film from the film to be processed by hydrophobic interaction; and
dissolving, by the dissolving solution, the film to be processed after the portion of the protective film is removed.

2. The method according to claim 1,
wherein the dissolving solution comprises at least one of a hydrogen fluoride aqueous solution, an ammonium fluoride aqueous solution, a potassium hydroxide aqueous solution, and an ammonia aqueous solution.

3. The method according to claim 1,
wherein the protective film is formed from a surfactant.

4. The method according to claim 1,
wherein the surface of the processing body comprises a polytetrafluoroethylene.

5. The method according to claim 1,
wherein removing the protective film comprises relatively moving the protective film and the processing body while the protective film is in contact with or close to the processing body.

6. The method according to claim 1,
wherein the film to be processed is a silicon oxide film, a silicon film, a silicon carbide film, a gallium nitride film, an aluminum oxide film, or a metallic film.

7. The method according to claim 1,
wherein the protective film is formed from a material that is insoluble or poorly soluble in the dissolving solution.

8. The method according to claim 1,
wherein the protective film is formed from an anionic, cationic, ampholytic, or non-ionic surfactant.

9. The method according to claim 1,
wherein the protective film is formed from a surfactant including a functional group of carboxylic acid type, sulfonic acid type, sulfate type, phosphate type, amine salt type, quaternary ammonium salt type, ether type, ester type, alkanolamide type, carboxybetaine type, or glycine type.

10. The method according to claim 1,
wherein the dissolving solution comprises a material for the protective film, and
the protective film is formed by supplying the dissolving solution onto the film to be processed.

11. The method according to claim 1,
wherein the processing body is brought into contact with or brought close to the protective film continuously or at a predetermined time interval during dissolving the film to be processed.

12. A chemical planarization apparatus comprising:
a holder to hold a substrate with a film to be processed formed on a surface thereof;
a container to store a pretreatment liquid for forming a hydrophobic protective film on the film to be processed;
a processing body with a hydrophobic surface, to be brought in contact with or close to the protective film of the substrate held in the holder; and
a supplier to supply, to a surface of the processing body, a dissolving solution that dissolves the film to be processed.
